(19) United States
(12) Patent Application Publication
(10) Pub. No.: US 2005/0005962 A1
(43) Pub. Date: Jan. 13, 2005

(54) Portable solar apparatus

(75) Inventors: Mark Bradford Clifton, West Windsor, NJ (US); Ivan Pawlenko, Holland, PA (US); Larry Samson, Langhome, PA (US)

Correspondence Address: SYNNESTVEDT & LECHNER, LLP, 2600 ARAMARK TOWER, 1101 MARKET STREET, PHILADELPHIA, PA, 191072950, US

(73) Assignee: Lucent Technologies Inc., Murray Hill, NJ (US)

(21) Appl. No.: 10/616,826

(22) Filed: Jul. 10, 2003

(51) Int. Cl. H01L 31/00

(52) U.S. Cl. 136/251; 136/291

(57) ABSTRACT

A portable solar apparatus is described. In one exemplary implementation, the apparatus includes a solar energy collector cell, and a portable substrate. The solar energy collector cell converts light energy received from a light source into electrical current for transfer to a device. The portable substrate supports the solar energy collector cell. In one exemplary implementation, the portable substrate is a sun shield for a vehicle.

### TECHNICAL FIELD

The present invention relates to solar energy collection.

### BACKGROUND

Sun shields are generally used to protect the interior of a vehicle from the damaging ultra violet light produced by the sun and to reduce interior temperatures of the vehicle when it is hot, such as during the summer. Typically, the sun shields are placed on the interior or exterior of a vehicle's window to block sun light. When not in use, most sun shields can be folded and stowed, such as in the trunk of an automobile.

### SUMMARY

A portable solar apparatus is described. In one exemplary implementation, the apparatus includes a solar energy collector cell, and a portable substrate. The solar energy collector cell converts light energy received from a light source into electrical current for transfer to a device. The portable substrate supports the solar energy collector cell. In one exemplary implementation, the portable substrate is a sun shield for a vehicle.

### BRIEF DESCRIPTION OF THE DRAWINGS

The detailed description is explained with reference to the accompanying figures. In the figures, the left-most digit(s) of a reference number identifies the figure in which the reference number first appears.

FIG. 1 illustrates various components of an environment in which a portable solar apparatus may be used to supply electrical current to one or more devices.

FIG. 2 shows a planar view of one exemplary implementation of a portable solar apparatus.

FIG. 3 shows a device integral to a portable solar apparatus.

### DETAILED DESCRIPTION

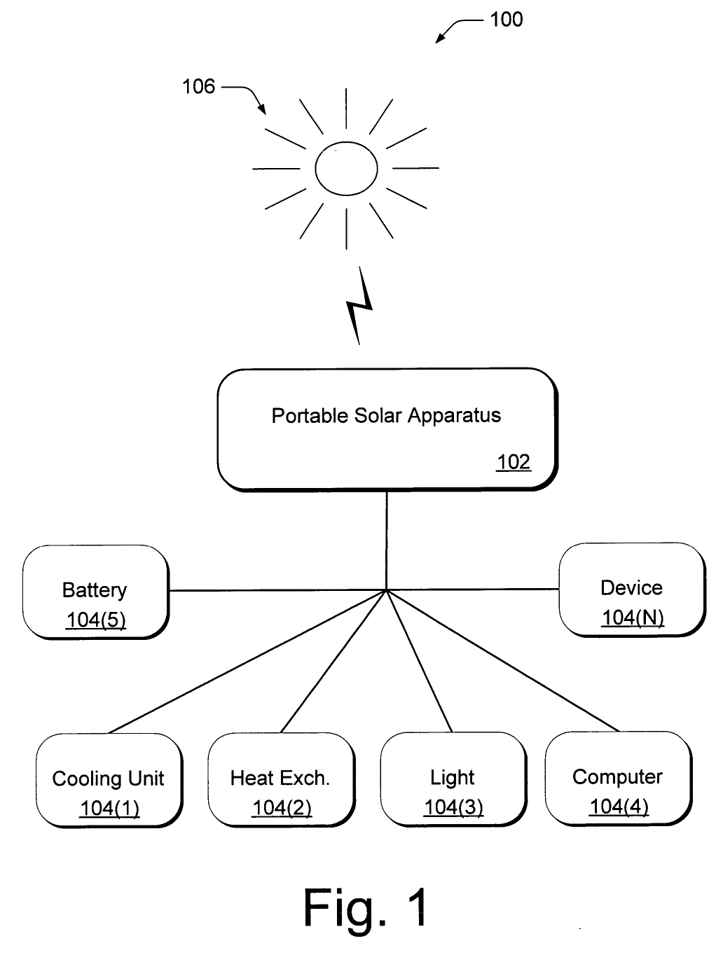

FIG. 1 illustrates various components of an environment 100 in which a portable solar apparatus 102 may be used to supply electrical current to one or more devices 104(1), . . . , 104(N). Apparatus 102 is configured to convert light energy received from a light source 106 into electrical current for supply to the devices referred to generally as reference number 104. Apparatus may be used in conjunction with a vehicle. For instance, apparatus 102 may be placed in the interior or exterior of a vehicle to collect light energy from light source 106. As used herein, a “vehicle” includes any type of vehicle such as, but not limited to, automobiles, trucks, airplanes, trains, boats, motorcycles, and other vehicles.

Alternatively, apparatus 102 may be placed on a building, tent, hut, house, storage shed, pool cabana, other structures, and enclosures, to collect energy from light source 106.

Devices 104 may include a cooling unit 104(1), a heat exchange unit 104(2), a light 104(3), a portable entertainment unit 104(3), a computer 104(4), a battery 104(5), and other electronic and/or electromechanical devices. For example, cooling unit 104(1) may represent a fan, a miniature air-conditioning unit, or related cooling devices. Heat exchange unit 104(2) may represent a water pump that circulates water heated by solar cells. Portable entertainment unit 104(3) may represent a radio, CD player or other entertainment device.

In most instances, the light source 106 is the sun, but light energy may be received from other sources, such as fluorescent lights, diodes, streetlights, and other light emitting sources.

Having introduced some of the higher-level aspects of environment 100, it is now possible to discuss some of the more specific embodiments of apparatus 102.

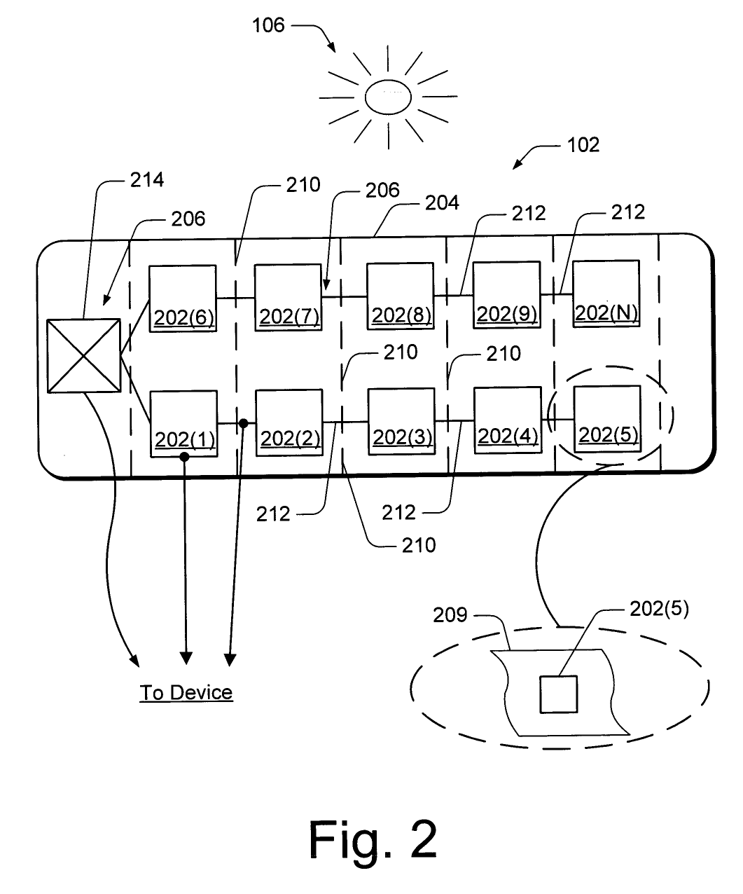

FIG. 2 shows a planar view of one exemplary implementation of apparatus 102. Apparatus 102 includes one or more solar energy collector cells 202(1), . . . , 202(N), a portable substrate 204, and a connector 206. Solar energy collector cells referred to generally as reference number 202 are configured to convert light energy received from a light source 106 into electrical current. In the exemplary implementation, solar energy collector cells are photovoltaic cells, but other types of cells capable of converting light energy into electrical energy also may be used.

Portable substrate 204 is configured to support solar energy collector cells 104. That is, portable substrate 204 serves as a platform for attaching solar energy collector cells 202. Fasteners, such as, for example clips, pins, thread, glue, tape, epoxy, Velcro, and other fastening devices may be used to attach the solar energy collector cells 104 to the portable substrate 204. Alternatively, cells 202 also may be integrated or embedded into the material of the portable substrate 204 by integrating the cells on a patch of material 209. The patch of material 209 containing one or more cells can then be attached to the portable substrate 204.

Portable substrate 204 is typically made of a lightweight material such as paper, cardboard, plastic and/or a combination of any these materials or related materials. Portable substrate 204 also may include one or more perforations 210 to permit the portable substrate 204 to be folded for easy storage and/or portability.

In one exemplary implementation, portable substrate 204 is a sun shield for vehicles. The sun shield may be used in connection with any part of a vehicle capable of being exposed to a light source. Typically, the sun shield is used on the interior or exterior side of a window, and in particular, the windshield of a vehicle.

Alternatively, portable substrate 204 may take the form of other portable devices, such as a vehicle cover used to protect the exterior of a vehicle from weather conditions and prevent the interior of vehicle from be exposed to heat produced by the sun.

Cells 202 are electrically connected to device(s) 104 via connector 206. That is, connector 206 is electrically coupled to the solar energy collector cells and is configured to transfer electrical current to device(s) 104.

In one exemplary implementation, connector 206 includes a network of wires 212 to provide a conduit to transfer electrical current produced by cells 202. Wires 212 may be connected directly to one or more devices 104. Wires 212 may be fastened to portable substrate 104 by any of the types of fasteners described above.

Alternatively, connector 206 may include a primary connector 214 and wires 212. Accordingly, wires 212 provide electrical conduits to transfer electrical current from cells 202 to primary connector 214. A device(s) 104 may be connected to primary connector 214. Primary connector 214 may take the form of a standard female or male plug to provide a convenient means to plug device(s) 104 into apparatus 102 (i.e., connect devices 104 to apparatus 102).

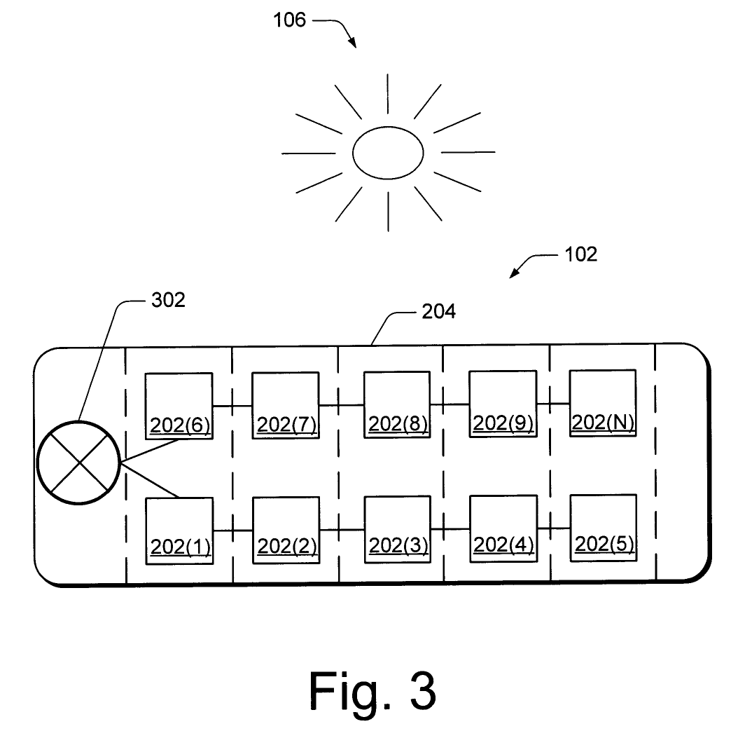

In either implementation, devices 104 may be connected to apparatus 102 remotely or be integrated directly onto portable substrate 204. For example, FIG. 3 shows a fan 302 integral to portable substrate 204. In other words, fan 302 is attached directly to portable substrate 204 by any of the fastening means described above.

Referring to FIGS. 1, 2 and 3, it should now be appreciated that energy collected via cells 202 are used to power device(s) 104. Device(s) 104 may be integrated directly into the portable substrate 204 (FIG. 3) or connected to portable substrate 204 via some sort of connector 206 (FIG. 2). A device 104 may be powered by the collective output of cells 102 or by one or more individual cells 102.

Accordingly, if apparatus 102 is part of a sun shield, the use of solar power should offer better cooling in a vehicle by circulating air in the vehicle by a solar powered fan, such as when the vehicle is parked. Additionally, by being portable, apparatus 102 enables devices to be powered when away from traditional electrical power sources, such as when camping or traveling.

Although the invention has been described in language specific to structural features and/or methodological acts, it is to be understood that the invention defined in the appended claims is not necessarily limited to the specific features or acts described. Rather, the specific features and acts are disclosed as exemplary forms of implementing the claimed invention.

1. An apparatus, comprising:
a solar energy collector cell configured to convert light energy received from a light source into electrical current for transfer to a device; and
a portable substrate configured to support the solar energy collector cell, the portable substrate is adapted to be used in conjunction with one of a vehicle, a storage shed, a camping tent, a hut, and a building.

2. The apparatus as recited in claim 1, further comprising a connector, coupled to the solar energy collector cell, configured to transfer the electrical current to a device.

3. The apparatus as recited in claim 1, wherein the portable substrate is a comprised of a foldable material.

4. The apparatus as recited in claim 1, wherein the portable substrate is a sun shield associated with vehicles.

5. The apparatus as recited in claim 1, wherein the device is integral to the portable substrate.

6. The apparatus as recited in claim 1, wherein the device is one of a fan, a cooling unit, a heat exchange unit, a portable entertainment unit, a computer, and a battery.

7. The apparatus as recited in claim 1, wherein the portable substrate is configured to be positioned on an interior or exterior side of a window.

8. The apparatus as recited in claim 1, wherein the solar energy collector cell is a photovoltaic cell connected to the portable substrate by a fastener.

9. A system for supplying power to a device, comprising:
solar energy collector cells configured to convert light energy received from a light source into electrical current;
a portable substrate configured to support the solar energy collector cells, the portable substrate is adapted to be used in conjunction with one of a vehicle, a storage shed, a camping tent, a hut, and a building; and
a connector, coupled to the solar energy collector cells configured to transfer the electrical current to the device.

10. The system as recited in claim 9, wherein the portable substrate is comprised of a foldable material.

11. The system as recited in claim 9, wherein the portable substrate is a sun shield associated with vehicles including a window.

12. The system as recited in claim 9, wherein the device is integral to the portable substrate.

13. The system as recited in claim 9, wherein the device is one of a fan, a cooling unit, a heat exchange unit, a portable entertainment unit, a computer, and a battery.

14. The system as recited in claim 9, wherein the portable substrate is configured to be positioned on an interior or exterior side of a window.

15. The system as recited in claim 9, wherein the solar energy collector cells are photovoltaic cells connected to the portable substrate by fasteners.

16. A sun shield for absorbing light entering a window, comprising:
solar energy collector cells configured to convert light energy received from a light source into electrical current,
a fastener configured to connect the solar energy collector cells to the sun shield, and
a connector, coupled to the solar energy collector cells configured to transfer the electrical current to a device.

17. The sun shield as recited in claim 16, wherein the device is one of a fan, a cooling unit, a heat exchange unit, a portable entertainment unit, a computer, and a battery.

18. The sun shield as recited in claim 16, wherein the solar energy collector cells are photovoltaic cells connected to the portable substrate by fasteners.

19. The sun shield as recited in claim 16, wherein the sun shield is adapted to be used in conjunction with one of a motor vehicle, an automobile, an airplane, a storage shed, a camping tent, a hut, and a building.
